(19) United States
(12) Patent Application Publication
(10) Pub. No.: US 2002/0084793 A1
(43) Pub. Date: Jul. 4, 2002

(54) Simultaneous testing of multiple optical circuits in substrate

(76) Inventors: Henry H. Hung, Phoenix, AZ (US); Yellapu Anjan, Scottsdale, AZ (US); Tamim El-Wailly, Peoria, AZ (US)

Correspondence Address: Tod R. Nissle, Esq., TOD R. NISSLE, P.C., P.O. Box 55630, Phoenix, AZ, 85078, US

(21) Appl. No.: 09/752,171

(22) Filed: Dec. 29, 2000

(51) Int. Cl. G01R 31/308

(52) U.S. Cl. 324/753

(57) ABSTRACT

An improved method and apparatus for testing an optical circuit simultaneously contacts and allows testing of a plurality of optical circuits in a substrate before the optical circuits are cut from the substrate.

This invention relates to test apparatus and methods.

More particularly, the invention relates to a method and apparatus for testing optical circuits.

Modulators or other optical circuits are formed in groups on semiconductor wafers or on substrates which comprise a part of a semiconductor wafer. Each wafer, or substrate on a wafer, includes one or more optical circuits.

An integrated optic chip (IOC) is made of an electro-optic material whose index of refraction increases or decreases depending on the direction of electric field applied to it. IOC's are analogous to integrated circuits (IC's) utilized in semiconductor technology. The signal processing in an IC is totally electric whereas in an IOC it is both optical and electrical. The term “integrated” in “integrated optic chip” implies that the chip has both electrical and optical parts. One or more external electrical signal(s) is applied to one or more electrodes formed on an IOC and the electrical signals change the index of refraction of one or more waveguides adjacent to the electrodes. Changing the index of refraction of a waveguide produces a concomitant change in the intensity and/or phase of light passing through the waveguide. An IOC device is a device which includes one or more IOCs.

An integrated optic device (IOD) is one of a class of devices for guiding and controlling light in thin film layers or in narrow waveguide channels formed in a suitable material. The suitable material normally comprises a dielectric. The IOD can comprise either a single type including transducers, filters, modulators, memory elements, and others or of several function applications (IOCs) combined (“integrated”) into a single device.

An optical circuit is a circuit which includes one or more IOCs, one or more IODs, or which transmits light through a solid material that comprises part of the circuit.

One problem associated with the production of optical circuits is testing the circuits to determine electro-optic characteristics such as the On-Off ratio and Vπ. Such testing usually necessitates connecting a light input fiber, a light output fiber, and a source of electricity to the optical circuit. When, for example, a plurality of optical circuits are formed on a single substrate, each circuit ordinarily is cut out of the substrate to be tested. Prior to testing each circuit, an electrical connection is provided for each optical circuit. Such electrical connections are typically achieved by bonding wire to an electrode in the optical circuit. Such a bond is time consuming to complete, introduces tolerance problems, and can be inadvertently broken and damage the optical circuit.

Accordingly, it would be highly desirable to provide an improved apparatus and method for forming an electrical contact with and testing an optical circuit.

Therefore, it is a principal object of the invention to provide an improved apparatus and method for testing an optical circuit.

A further object of the invention is to provide an apparatus and method for forming an electrical contact with an optical circuit while minimizing the likelihood that the optical circuit will be damaged.

Another object of the invention is to provide an apparatus and method for simultaneously testing a plurality of optical circuits.

These and other, further and more specific objects of the invention will be apparent to those skilled in the art from the following detailed description thereof, taken in conjunction with the drawings, in which:

FIG. 1 is a perspective view illustrating a plurality of substrates in a wafer;

FIG. 2 is a top view illustrating one of the substrates of FIG. 1 after the substrate has been removed from the wafer of FIG. 1;

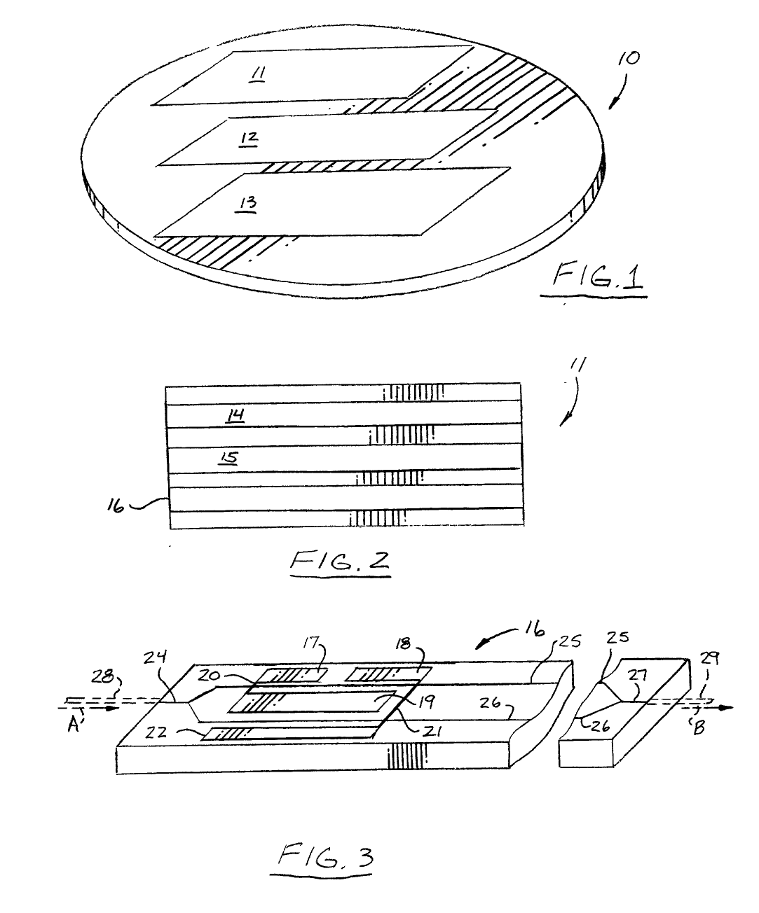

FIG. 3 is a perspective view illustrating a modulator after it has been removed from the substrate of FIG. 2; and,

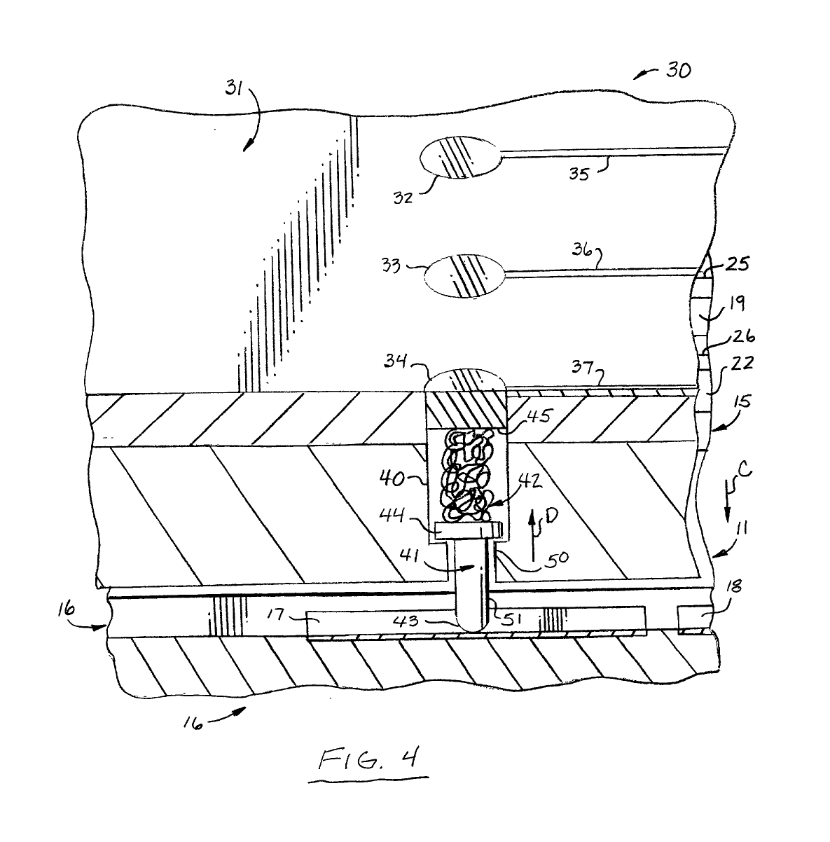

FIG. 4 is a partial section view of apparatus utilized to test optical circuits in accordance with the invention.

Briefly, in accordance with the invention, I provide an improved apparatus for forming an electrical contact with an optical circuit. The apparatus comprises a housing; an electrically conductive member mounted in the housing; and, a system mounted in the housing to permit the electrically conductive member to be displaced into the housing when the member contacts the optical circuit and the housing continues to move toward the optical circuit.

In another embodiment of the invention, I provide apparatus to electrically connect simultaneously to each of a plurality of optical circuits on a substrate. The apparatus includes a plurality of contacts each shaped and dimensioned and positioned to contact a different one of the optical circuits at the same time the remaining ones of the contacts are each in contact with one of the others of the optical circuits.

In a further embodiment of the invention, I provide a method for forming an electrical contact with an optical circuit. The method includes the step of contacting a portion of the optical circuit with a displaceable electrically conductive member

Turning now to the drawings, which depict the presently preferred embodiments of the invention without limitation of the scope thereof, and in which like reference characters refer to corresponding elements throughout the several views, FIG. 1 illustrates a semiconductor or other wafer 10 including a plurality of substrates 11 to 13. Each substrate includes a plurality of modulators or other optical circuits. For example, in FIG. 2, substrate 13 includes three modulators 14, 15, 16. The number of substrates in a wafer 10 can vary as desired. The number of optical circuits in a substrate (or a wafer) can vary as desired.

Although the construction of each modulator 14-16 or other optical circuit can vary as desired, for purposes of analysis of the embodiment of the invention shown in the drawings, it is assumed that the structure of each modulator 14-16 is identical.

In FIG. 3, modulator 16 includes a waveguide 24 which splits into a pair of waveguides 25 and 26. Waveguides 25 and 26 combine to form waveguide 27. Electrically conductive plates 17, 18, 19, 22 are formed on modulator 16. Electrically conductive lead 20 interconnects plates 17 and 19. Electrically conductive lead 21 interconnects plates 18 and 22. When modulator 16 is mounted in a housing, plates 17 and 18 are connected to a pair of DC pins mounted in the wall of the housing so that direct current can be input into modulator 16.

During the testing of modulator 16, an optical fiber 28 is positioned adjacent waveguide 24 to introduce light into waveguide 24. One electrical contact is connected to plate 17. A second electrical contact is connected to plate 18. The electrical contacts are utilized to deliver direct current to plates 17 and 18. When direct current is being applied to plates 17 and 18, light which is output from waveguide 27 to a fiber 29 positioned adjacent waveguide 27 is analyzed to determine any changes which occur in the properties of the light as it travels from waveguide 24 and through waveguides 25 and 26 past plates 17, 18, 19, 22. As noted earlier, conventional electrical contacts comprise wires that are bonded or welded to plates 17 and 18. The electrical contacts of the invention are illustrated in FIG. 4.

The electrical contact apparatus of FIG. 4 includes panel member 31. A plurality of electrically conductive contacts 32, 33, 34 are mounted in panel 31. A wire 35 to 37 or other electrically conductive lead delivers electricity to each contact 32, 33, 34, respectively. The structure of panel 31 immediately beneath contact 34 is illustrated in FIG. 4 and includes a cylindrical opening 40 and a cylindrical opening 50. Pin 41 includes cylindrical head 44 connected to cylindrical body 51. Body 51 includes arcuate foot 43. Head 44 is slidably mounted in cylindrical opening 40. Body 51 is slidably mounted in opening 50. Foot 43 extends downwardly from opening 50. A mass of fine elastic gold wire or mesh 42 extends and contacts both the bottom surface 45 of contact 34 and the head 44 of pin 41. The gold mesh 42 permits electricity to flow from contact 34 to head 44. Mesh 42 is elastic. When pin 41 is upwardly displaced in the direction of arrow D (and head 44 slides upwardly in the direction of arrow D) in opening 40, mesh 42 is compressed. When the force that pushes pin 41 in the direction of arrow D is released or removed, elastic mesh 42 expands in the direction of arrow C.

One important function of mesh 42 is that it permits pin 41 to be displaced upwardly in the direction of arrow D when foot 43 contacts a plate 17 and panel 31 continues to move downwardly toward plate 17 in the direction of arrow C. This minimizes the risk that foot 43 and pin 41 will generate enough pressure on plate 17 to damage plate 17 and modulator 16.

The structure of panel 31 immediately beneath contacts 32 and 33 is identical to that of the structure shown in FIG. 4 for contact 34. For example, contact 33 (and contact 32) has openings 40 and 50, a pin 41, and mesh 42 located beneath contact 33. Contacts 32, 33, 34 are in fixed position in panel 31.

Panel 31 is constructed and shaped and dimensioned so that a substrate 11 can be positioned beneath panel 31 and panel 31 lowered so that simultaneously (1) the foot 43 of the pin 41 beneath contact 34 contacts panel 17 of modulator 16; (2) the foot 43 of the pin 41 beneath contact 33 contacts panel 17 of modulator 15; and (3) the foot 43 of the pin 41 beneath contact 32 contacts panel 17 of modulator 14. When this occurs direct current or some other desired signal can be directed through contacts 32, 33, 34 into plates 17 of modulators 14, 15, 16, respectively. The physical properties of the current directed into contact 32 can be the same as or can differ from the physical properties of the current directed into contacts 33 and 34.

Further, although not shown in FIG. 4, an additional set of contacts 32A, 33A, 34A—each with its own operatively associated pin 41 and mesh 42—can be provide in panel 31. Each pin 41 in this additional set of contacts would contact one of panels 18 found in modulators 14, 15, 16. This permits a total of six plates (the three plates 17 and the three plates 18 found collectively in modulators 14 to 16) each to be contacted simultaneously by one of the pins 41. Each modulator has only one plate 17 and one plate 18. This also permits direct current to be delivered to plates 17 and 18 in modulator 16 at the same time that direct current is delivered to plates 17 and 18 in modulators 14 and 15. As a result, when the panel 31 depicted in FIG. 4 is utilized, a plurality of modulators 14 to 16 can be tested simultaneously while the modulators are still in a substrate 11 (FIG. 2) that has been removed from wafer 10. The number of modulators 14 to 16 in a substrate can vary as desired and is two or more.

In use, it is assumed for sake of example that (1) a substrate 11 includes three modulators 14 to 16, and (2) panel 31 includes six contacts and that each contact is operatively associated with mesh 42 and a pin 41 extending downwardly from the contact in the manner illustrated in FIG. 4 for contact 34. Three of the contacts are contacts 32, 33, and 34. For sake of this example, the three remaining contacts—which are not visible in FIG. 4 but are each identical in structure to contact 34 and its associated pin 41, apertures 40 and 50, and mesh 42—are referred to as contacts 32A, 33A, and 34A.

The pin 41 (not visible in FIG. 4) under contact 32 contacts plate 17 of modulator 14 when panel 31 is placed over and in registration with substrate 11 and is lowered downwardly until foot 43 contacts plate 17 of modulator 14 and pin 41 is slidably displaced a short distance upwardly in the direction of arrow D against mesh 42.

The pin 41 (not visible in FIG. 4) under contact 33 contacts plate 17 of modulator 15 when panel 31 is placed over and in registration with substrate 11 and is lowered downwardly until foot 43 contacts plate 17 of modulator 15 and pin 41 is slidably displaced a short distance upwardly in the direction of arrow D against mesh 42.

The pin 41 under contact 34 contacts plate 17 of modulator 16 when panel 31 is placed over and in registration with substrate 11 and is lowered downwardly to the position shown in FIG. 4 so that foot 43 contacts plate 17 of modulator 16 and pin 41 is slidably displaced a short distance upwardly in the direction of arrow D against mesh 42. In FIG. 4, foot 43 of pin 41 has just contacted plate 17 and has been displaced only a short distance in the direction of arrow D.

The pin 41 (not visible in FIG. 4) under contact 32A contacts plate 18 of modulator 14 when panel 31 is placed over and in registration with substrate 11 and is lowered downwardly to the position shown in FIG. 4 so that foot 43 contacts plate 18 of modulator 14 and pin 41 is slidably displaced a short distance upwardly in the direction of arrow D against mesh 42.

The pin 41 (not visible in FIG. 4) under contact 33A contacts plate 18 of modulator 15 when panel 31 is placed over and in registration with substrate 11 and is lowered downwardly to the position shown in FIG. 4 so that foot 43 contacts plate 18 of modulator 15 and pin 41 is slidably displaced a short distance upwardly in the direction of arrow D against mesh 42.

The pin 41 (not visible in FIG. 4) under contact 34A contacts plate 18 of modulator 16 when panel 31 is placed over and in registration with substrate 11 and is lowered downwardly to the position shown in FIG. 4 so that foot 43 contacts plate 18 of modulator 16 and pin 41 is slidably displaced a short distance upwardly in the direction of arrow D against mesh 42.

When each of the plates 17 and 18 of the modulators 14 to 16 in a substrate 11 are contacted, direct current or another desired signal can be applied simultaneously to each of modulators 14 to 16. Before direct current is applied simultaneously to each of modulators 14 to 16, each modulator is supplied with an optical fiber 28 which inputs light into the modulator and with an optical fiber 29 which receives the light output by waveguide 27 of the modulator (FIG. 3). While light from optical fiber 28 passes through the waveguides 24 et al. in each modulator, direct current is applied by panel 31 to plates 17 and 18 of the modulator. The light output by waveguide 27 is received by optical fiber 29 and transmitted to apparatus which analyzes the light to evaluate the physical properties of the modulator.

Another elastic electrically conductive material can, if desired, be utilized in place of gold mesh 42. For example, silver mesh can be utilized, or a polymer coated with an electrically conductive material can be utilized, or a metal spring can be utilized, etc.

A broadband light source is used to provide light to an optical fiber 28 that inputs light to a modulator 14 to 16 or optical circuit being tested.

Have described the presently preferred embodiments of the invention in such terms as to enable those of skill in the art to understand, make and use the invention,

I claim:

1. Apparatus for forming an electrical contact with an optical circuit, said apparatus comprising
(a) a housing;
(b) an electrically conductive member mounted in said housing; and,
(c) means mounted in said housing to permit said electrically conductive member to be displaced into said housing when said member contacts the optical circuit and said housing continues to move toward said optical circuit.

2. Apparatus to electrically connect simultaneously to each of a plurality of optical circuits on a substrate, including a plurality of contacts each shaped and dimensioned and positioned to contact a different one of said optical circuits at the same time the remaining ones of said contacts are each in contact with one of the others of said optical circuits.

3. A method for forming an electrical contact with an optical circuit, including the step of contacting a portion of said optical circuit with a displaceable electrically conductive member
